(19) United States
(12) Patent Application Publication
(10) Pub. No.: US 2019/0245491 A1
(43) Pub. Date: Aug. 8, 2019

(54) TDD TRANSMIT-RECEIVE FRONT END CIRCUIT WITHOUT A RF T-R SWITCH

(71) Applicant: DUET MICROELECTRONICS INC., Raritan, NJ (US)

(72) Inventor: Robert Bayruns, Raritan, NJ (US)

(73) Assignee: DUET MICROELECTRONICS INC., Raritan, NJ (US)

(21) Appl. No.: 16/255,932

(22) Filed: Jan. 24, 2019

Related U.S. Application Data
(60) Provisional application No. 62/627,998, filed on Feb. 8, 2018.

(51) Int. Cl. H03F 1/26; H03F 3/21; H04B 1/04; H04B 1/00; H04B 1/44; H04J 3/16

(52) U.S. Cl. CPC H03F 1/26; H03F 3/21; H04J 3/1694; H04B 1/0057; H04B 1/44; H04B 1/0458

(57) ABSTRACT

A transmit-receive (T-R) circuit is switchable for both small and large signals using a high impedance low noise amplifier, which lacks T-R switches, and which permits implementation using only bipolar transistors for integration into the fabrication of integrated circuits. The relatively large T-R switch loss is eliminated, resulting in better efficiency in operation of the T-R circuit. When the T-R circuit is in a transmit mode, a power amplifier is in an ON state, and the low noise amplifier is in an OFF state, such that the low noise amplifier has a high impedance between the LNA input and the LNA output to block a first signal from the LNA input from reaching the antenna. When the T-R circuit is in a receive mode, the power amplifier is in an OFF state, and the low noise amplifier is in an ON state with a low impedance.

### CROSS-REFERENCE TO RELATED APPLICATION

This application claims priority to U.S. Provisional Application No. 62/627,998, filed on Feb. 8, 2018, which is incorporated by reference in its entirety.

### BACKGROUND OF THE INVENTION

### 1. Field of the Invention

The present invention relates to transmit-receive (T-R) circuits, and in particular to a transmit-receive circuit without a T-R switch.

### 2. Description of Prior Art

Time-division duplex (TDD) circuits apply time-division multiplexing to separate outbound and inbound signals in a communication system. As shown in FIG. 1, a basic T-R circuit 10 in the prior art includes a power amplifier (PA) 12 which receives an input signal from an input port or pin 14, and which outputs an amplified signal for transmission by an antenna 16. A low noise amplifier (LNA) 18 is also connected to the antenna 16 for receiving and amplifying a very low-power signal received from the antenna 16 without significantly degrading the signal-to-noise ratio (SNR) of the signal, with the low-noise amplified signal being output to an output port or pin 20. A T-R switch 22 is connected to the antenna 16, the PA 12, and the LNA 18 for selectively switching the antenna 16 to the PA 12 during a transmission mode, and for selectively switching the antenna 16 to the LNA 18 during a receiving mode.

The T-R switch 22 is used to allow for separate input matches for LNA and PA outputs. The T-R switch 22 also prevents the LNA 18 from distorting the PA output, and also prevents a large PA output from damaging the LNA 18 due to high input currents.

However, in the prior art, the T-R switch 22 is typically implemented using a field-effect transistor (FET) or a PIN diode, which introduces a radio frequency (RF) signal loss of about 1 dB to about 2 dB. In addition, inclusion of the T-R switch 22 increases the fabrication cost of the T-R circuit 10. Furthermore, when the T-R circuit 10 is fabricated on an integrated circuit (IC), it is often difficult to integrate the T-R switch 22 into the integrated circuit.

Therefore, a need exists for a T-R circuit with improved RF power output by eliminating RF signal losses due to a T-R switch. A need also exists for a lower cost of fabrication of the T-R circuit. A need further exists for a T-R circuit implemented using bipolar transistors only, especially at the T-R front end, which permits integration of the T-R circuit on an integrated circuit.

In addition, one disadvantage of T-R circuits in the prior art is the use of prior art LNAs 24, 26, such as shown in FIGS. 2-3, respectively. The prior art LNAs in transmit mode have an RF path which experiences the transistors as if one or more of the transistors was a diode or a large capacitor under a large signal.

Therefore, a need also exists for an LNA which does not have an RF path which experiences the transistors as if one or more of the transistors was a diode or a large capacitor under a large signal.

One alternative to the prior art T-R circuits is to implement a TDD transceiver 28 using circulators and isolators in the prior art, as shown in FIG. 4. Although the T-D switch 22 in FIG. 1 is eliminated, such circulators and isolators are relatively large in size and use expensive magnetic devices.

Another alternative to the prior art T-R circuits is to implement an IC architecture 30 with ¼ wave transmission lines in the front ends (FEs) between a splitter/combiner and an antenna, as shown in FIG. 5 and described in the prior art in B. Sadhu et al., “A 28 GHz 32-Element Phased Array Transceiver IC with Concurrent Dual Polarized Beams and 1.4 Degree Beam-Steering Resolution for 5G Communication”, IEEE ISSCC, 2017. As shown in FIG. 6 and described in the Sadhu reference, the front-end 32 uses ¼ wave transmission lines 34 between the PA 36 and the LNA 38. More specifically, the front-end 32 has a T-line based loss invariant 5-bit 5 degree/step phase shifter 40 coupled to the splitter/combiner in FIG. 5, a switch SW2 42 using a ¼ wavelength T-line switch, and a TX phase invariant variable gain amplifier (VGA) 44 plus a 1-bit 180 degree phase shifter connected to a cascode PA 36 coupled to a switch SW1 34 as a T-R switch connected to the antenna. A common emitter LNA 38 and an RX phase invariant VGA 46 plus a 1-bit 180 degree phase shifter are also connected to the antenna and the switch SW2 42. When the LNA 38 is OFF, a bipolar switch presents a short at the LNA 38 and an open circuit at the PA 36.

One disadvantage of the front end circuits shown in FIGS. 5-6 is that it is limited to low power applications. In addition, as shown in FIG. 7, the switch SW1 50 in the prior art is connected to a PA 52 and an LNA 54. However, the switch SW1 50 uses an asymmetrical switch S3 56 which adds distortion, and the switch SW1 50 requires a high impedance PA 52 by switching with output PA matching, at switch S1 58, which is limited to very low power applications and also adds distortion. FIG. 8 shows a Smith chart for operation of the traditional T-D switch in receive (RX) mode with impedances Z when the PA 52 is OFF, and while operating from 26 GHz to 30 GHz, and for the operation of the switches S1, S2, and S3 is shown in FIG. 7.

Therefore, a need also exists for an improved T-R circuit without the distortion and without the limitation to low power applications, as experienced in the prior art T-R circuits in FIGS. 5-7.

### OBJECTS AND SUMMARY OF THE INVENTION

The following presents a simplified summary of some embodiments of the invention in order to provide a basic understanding of the invention. This summary is not an extensive overview of the invention. It is not intended to identify key/critical elements of the invention or to delineate the scope of the invention. Its sole purpose is to present some embodiments of the invention in a simplified form as a prelude to the more detailed description that is presented later.

The present invention provides a T-R circuit which is switchable for both small and large signals using a high impedance (Z) LNA, which lacks T-R switches in the prior art, and which permits implementation using only bipolar transistors for integration into the fabrication of integrated circuits. The relatively large T-R switch signal loss of prior art T-R switches is eliminated in the T-R circuit of the present invention, resulting in better efficiency in operation of the inventive T-R circuit.

In one embodiment, the present invention is a circuit including: a power amplifier (PA) having a PA output operatively connected to an antenna; and a low noise amplifier (LNA) having: an LNA input connected to the antenna; and an LNA output; wherein when the circuit is in a transmit mode, the power amplifier is in an ON state, and the low noise amplifier is in an OFF state, whereby the low noise amplifier has a high impedance between the LNA input and the LNA output to block a first signal from the LNA input from reaching the antenna. The high impedance is about 50 ohms. When the circuit is in a receive mode, the power amplifier is in an OFF state, and the low noise amplifier is in an ON state, whereby the low noise amplifier has a low impedance between the LNA input and the LNA output to allow a second signal from the antenna to be amplified by the low noise amplifier for output at the LNA output. The low impedance is about 3 ohms. The low noise amplifier further includes a plurality of transistors which are only bipolar transistors. Alternatively, the low noise amplifier further includes a plurality of transistors including at least one bipolar transistor and at least one field-effect transistor. The circuit may have an inductor in series between the power amplifier and the antenna; and a first capacitor in parallel with the inductor. A second capacitor may be in parallel with the power amplifier. Alternatively, the circuit may have a resistor and a capacitor in parallel with the low noise amplifier; and wherein the parallel combination of the resistor, the capacitor, and the low noise amplifier is in series with the antenna.

In another embodiment, the present invention is a time-division duplex (TDD) circuit including: a power amplifier (PA) having a PA output operatively connected to an antenna; and a low noise amplifier (LNA) having: an LNA input connected to the antenna; and an LNA output; wherein when the circuit is in a transmit mode, the power amplifier is in an ON state, and the low noise amplifier is in an OFF state, whereby the low noise amplifier has a high impedance between the LNA input and the LNA output to block a first signal from the LNA input from reaching the antenna; and wherein when the circuit is in a receive mode, the power amplifier is in an OFF state, and the low noise amplifier is in an ON state, whereby the low noise amplifier has a low impedance between the LNA input and the LNA output to allow a second signal from the antenna to be amplified by the low noise amplifier for output at the LNA output. The high impedance is about 50 ohms. The low impedance is about 3 ohms. The low noise amplifier further includes a plurality of transistors which are only bipolar transistors. Alternatively, the low noise amplifier further includes a plurality of transistors including at least one bipolar transistor and at least one field-effect transistor. The TDD circuit may have an inductor in series between the power amplifier and the antenna; and a first capacitor in parallel with the inductor. A second capacitor may be in parallel with the power amplifier. Alternatively, the TDD circuit may include a resistor and a capacitor in parallel with the low noise amplifier; and wherein the parallel combination of the resistor, the capacitor, and the low noise amplifier is in series with the antenna.

In a further embodiment, the present invention is a low noise amplifier (LNA) including an LNA input; an LNA output; and a plurality of transistors in series; wherein when the low noise amplifier is in an OFF state, the low noise amplifier has a high impedance between the LNA input and the LNA output to block a first signal from the LNA input; and wherein when the low noise amplifier is in an ON state, the low noise amplifier has a low impedance between the LNA input and the LNA output to allow a second signal at the LNA input to be amplified by the low noise amplifier for output at the LNA output. The plurality of transistors is in a cascode configuration, are reverse biased, and has a low capacitance. At least two of the plurality of transistors are field-effect transistors (FETs).

### BRIEF DESCRIPTION OF THE DRAWINGS

The foregoing summary, as well as the following detailed description of presently preferred embodiments of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 illustrates a T-R circuit of the prior art;

FIGS. 2-3 illustrate LNA circuits of the prior art;

FIG. 4 illustrates another T-R circuit of the prior art which uses a circulator and an isolator;

FIGS. 5-7 illustrate examples of T-R circuits of the prior art using ¼ wave transmission lines;

FIG. 8 is a Smith chart for the prior art T-R switch in FIG. 7;

FIG. 9 illustrates a T-R circuit of the present invention;

FIG. 9A is a Smith chart for the T-R circuit in FIG. 9;

FIG. 10 illustrates an alternative embodiment of the T-R circuit of the present invention in receive mode;

FIG. 11 illustrates an equivalent circuit of the circuit of FIG. 9 in receive mode;

FIG. 12 is a graph simulating an input match at about 28 GHz;

FIG. 13 illustrates an equivalent circuit of the circuit of FIG. 9 in transmit mode;

FIG. 14 illustrates a high impedance LNA circuit of the present invention in transmit mode;

FIG. 15 illustrates an alternative embodiment of a high impedance LNA circuit of the present invention in transmit mode;

FIGS. 16-17 are graphs of power amplifier gain versus output power of the present invention; and

FIGS. 18-19 illustrate alternative embodiments of the high impedance LNA circuit of the present invention using FETs.

To facilitate an understanding of the invention, identical reference numerals have been used, when appropriate, to designate the same or similar elements that are common to the figures. Further, unless stated otherwise, the features shown in the figures are not drawn to scale, but are shown for illustrative purposes only.

### DETAILED DESCRIPTION OF THE PREFERRED EMBODIMENTS

Certain terminology is used in the following description for convenience only and is not limiting. The article “a” is intended to include one or more items, and where only one item is intended the term “one” or similar language is used. Additionally, to assist in the description of the present invention, words such as top, bottom, upper, lower, front, rear, inner, outer, right and left may be used to describe the accompanying figures. The terminology includes the words above specifically mentioned, derivatives thereof, and words of similar import.

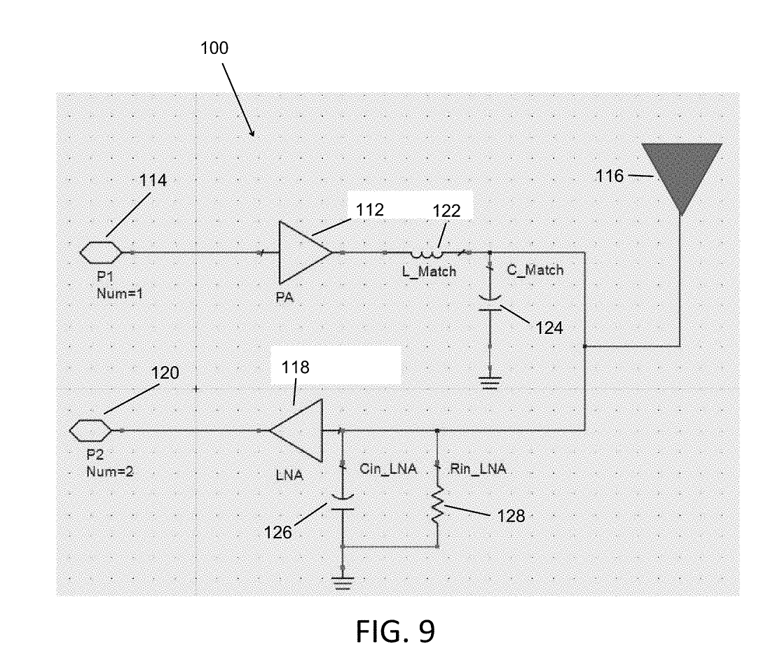

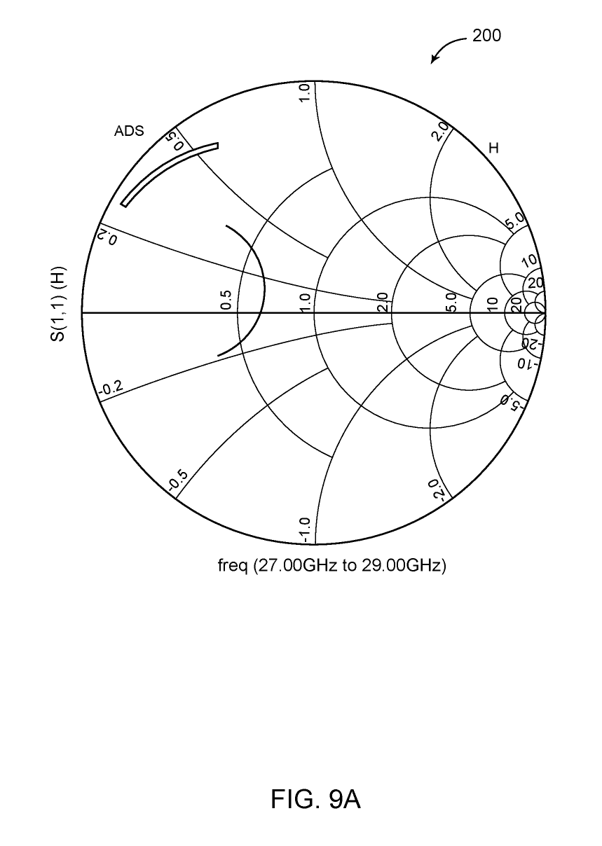

FIG. 9 shows the basic block diagram of the T-R circuit 100 of the present invention, which includes a low noise amplifier (LNA) 118 with a high impedance Z and having an output 120, and a power amplifier (PA) 112 having an input 114. The input and output of the LNA 118 and the PA 112, respectively, are directly or operatively connected to an antenna 116, respectively. The output of the PA 112 is connected to a first matching circuit which includes a matching inductor 122 and a matching capacitor 124 which are coupled to the antenna 116. The input of the LNA 118 is a second matching circuit which includes a capacitor 126 in parallel with a resistor 128, coupled to the input of the LNA 118 and to the antenna 116. The capacitor 126 may be, for example, a 0.27 pF capacitor.

The key points of the T-R circuit 100 of the present invention are: (i) there is no T-R switch; (ii) the LNA input and the PA output are directly or operatively connected at the antenna 116; (iii) the LNA input match is comprised of the LNA capacitance and resistive components and the PA output matching components; (iv) when the LNA 118 is switched OFF, the LNA 118 goes into a high impedance, low capacitance state; and (v) under large PA output powers, the LNA capacitances and/or diodes are not turned ON by the large positive or negative voltages. The PA 112 and the LNA 118 may be controlled and switched to respective ON and OFF states by any type of switching method known in the art.

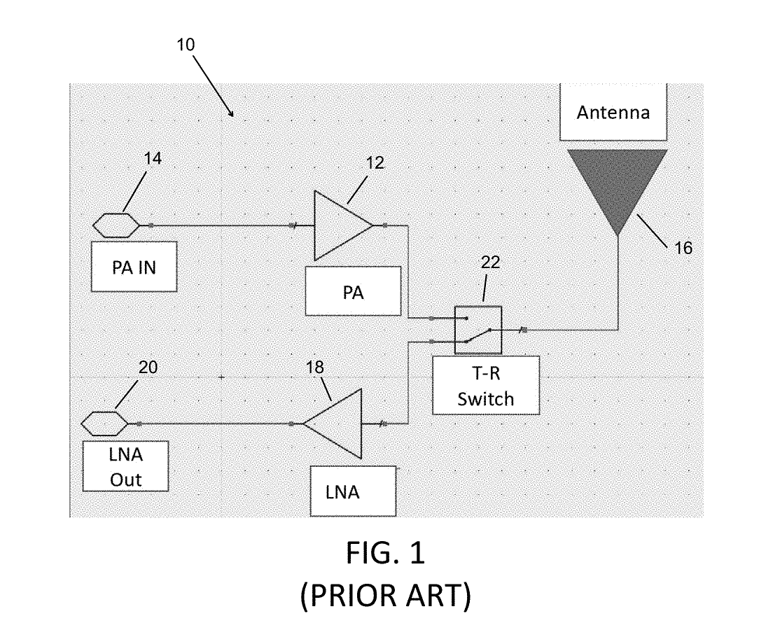

The T-R switch 22 in the prior art, shown in FIG. 1, which may be a FET or a PIN diode, has a series resistance when turned ON, which creates a loss of signal strength, decreases the efficiency of the PA 12, and adds noise to the LNA 18. By eliminating the T-R switch 22, the T-R circuit 100 of the present invention, shown in FIG. 9, eliminates such signal losses, maintains or improves the efficiency of the PA 112, and prevents the addition of noise to the LNA 118.

For the inventive circuit 100 of FIG. 9, when in transmit (TX) mode, the PA 112 is ON, the LNA 118 is switched OFF, and the LNA 118 goes into a high impedance (Z) state for both large and small signals. When in receive (RX) mode, the PA 112 is turned OFF, the LNA 118 is turned ON, and the LNA 118 absorbs the PA output match into the LNA input. For example, when LNA 118 is turned ON, the impedance at the input of the LNA 118 is designed to be close to about 3 ohms. When the LNA 118 is turned OFF, the LNA 118 has a high impedance between the input of the LNA 118 and the output 120, such that the LNA 118 in the OFF state, during TX mode, looks like an approximate 50 ohm resistor in series with the 0.27 pF capacitor 126. The 0.27 pF capacitor 126 becomes part of the PA output matching element.

As shown in FIG. 9A, a Smith chart 200 is illustrated for the T-R circuit 100 in FIG. 9, with the input LNA impedance (S1,1) in transmit mode and receive mode operating from 27 GHz to 29 GHz.

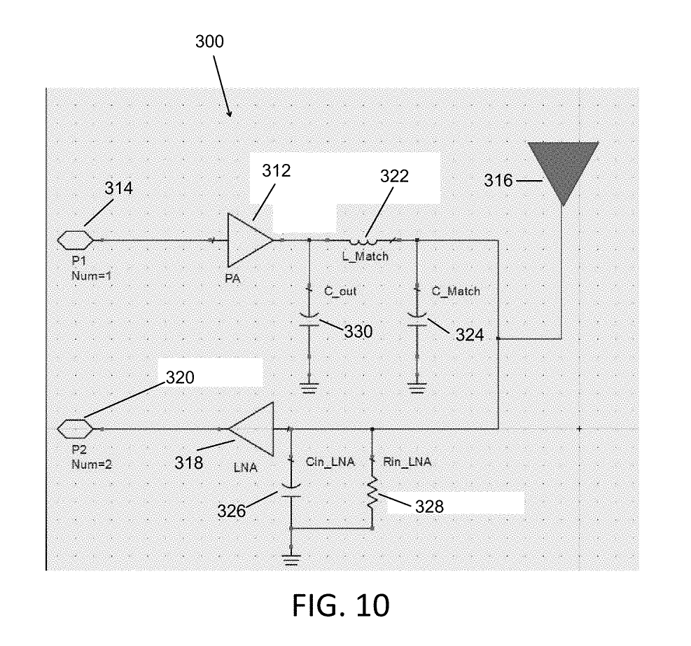

FIG. 10 is an alternative embodiment of the T-R circuit 300 of the present invention in receive mode, with the components 312, 314, 316, 318, 320, 322, 324, 326, 328 being identical to the components 112, 114, 116, 118, 120, 122, 124, 126, 128, respectively, of the circuit 100 in FIG. 9, with the circuit 300 in FIG. 10 also including an output capacitor Cₒᵤₜ 330 at the output of the PA 312. In the T-R circuit 300, when the high impedance LNA 318 is turned ON, and the PA 312 is switched OFF, Cₒᵤₜ is still being shorted for any alternating current (AC).

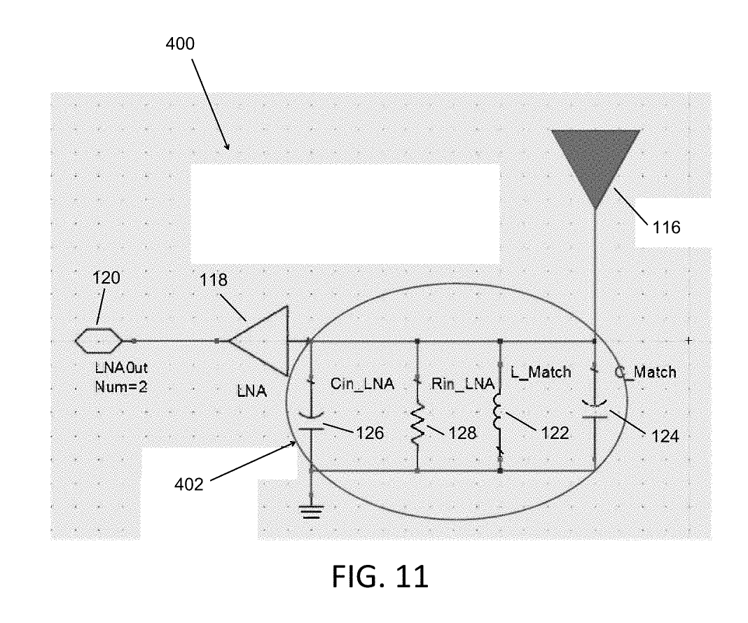

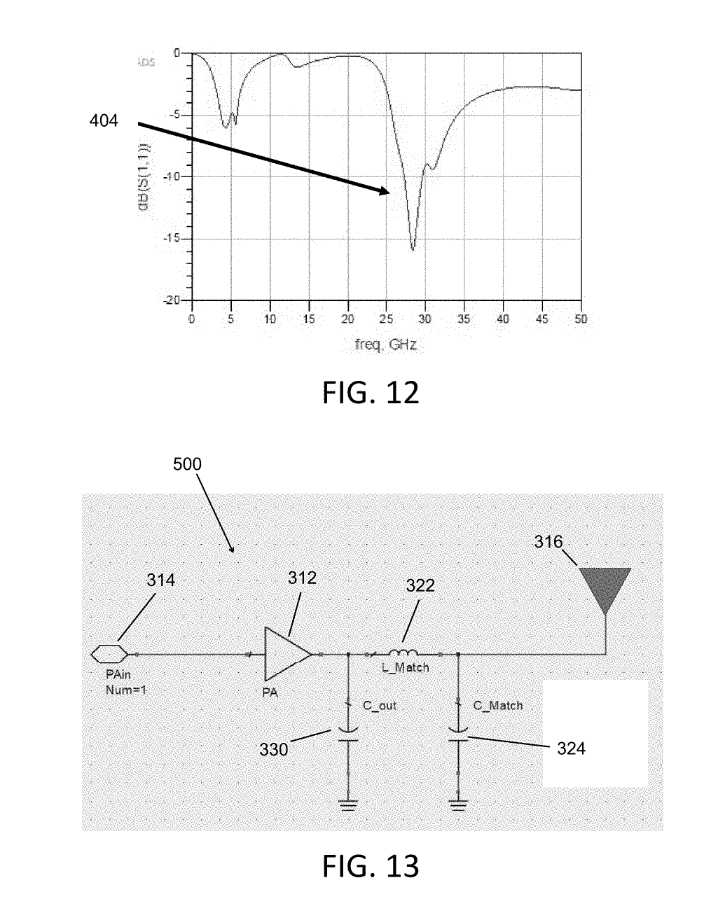

FIG. 11 is an equivalent circuit 400 of the circuit 100 of FIG. 9 in receive mode, forming a parallel resonant circuit 402 with the PA output match components 122, 124 absorbed into the LNA input of the bandpass LNA 118. The output impedance of the high impedance LNA 118 matches the bandpass input. FIG. 12 is a graph simulating an input match 404 for the LNA 118 at about 28 GHz.

FIG. 13 is an equivalent circuit 500 of the alternative circuit 300 of FIG. 10 in transmit mode, in which the LNA 318 is switched OFF for large and small signals due to the high impedance state of the LNA 318.

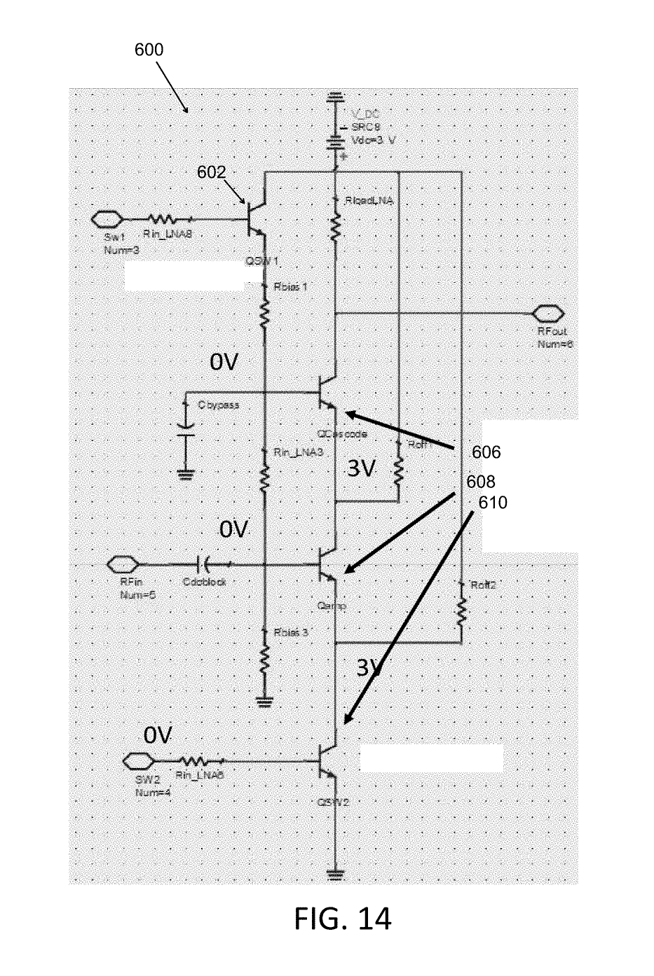

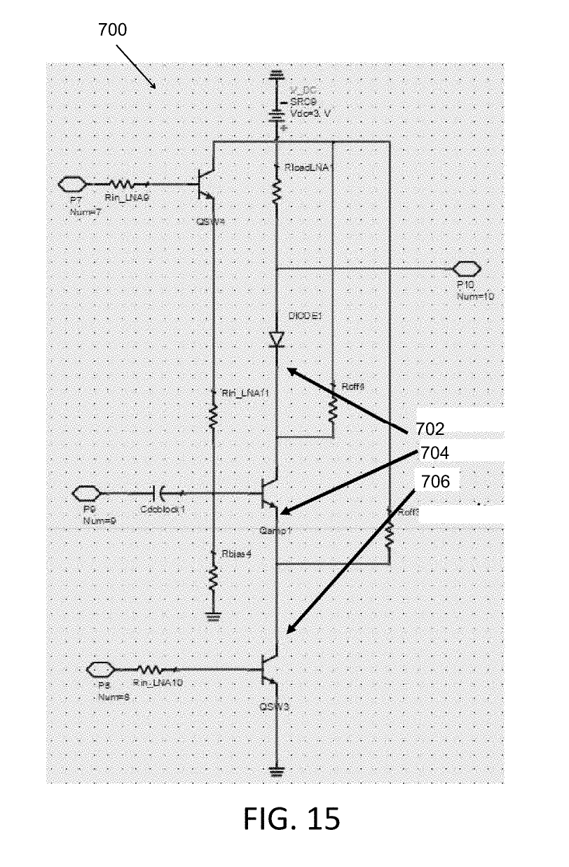

FIG. 14 is a high impedance LNA circuit 600 of the present invention in transmit mode, with the uppermost transistor QSW1 602 and the lowermost transistor QSW2 610 being switched to an open state, and a cascode of transistors 606, 608, 610 being reverse biased and having a low capacitance. The use of a cascode design in the circuit 600 has more gain than other circuits. FIG. 15 is an alternative embodiment 700 of a high impedance LNA circuit of the present invention in transmit mode without a cascode of transistors, but instead having a diode 702 and the transistors Qamp1 704 and QSW3 706 being reverse biased and having a low capacitance. The diode 702 serves to isolate the reverse bias, and the design of the circuit 700 with the diode 702 has less distortion. The LNA circuits 600, 700 in FIGS. 14-15 may be implemented using only bipolar transistors which facilitates integration of the LNA circuits 600, 700 into the fabrication of integrated circuits.

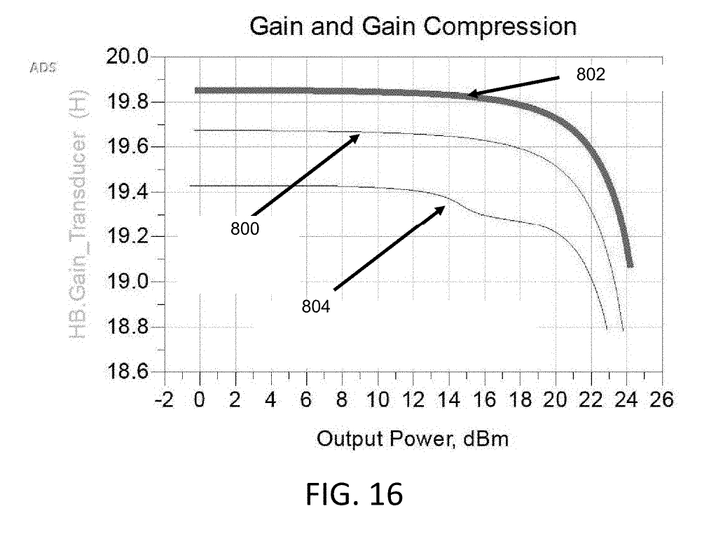

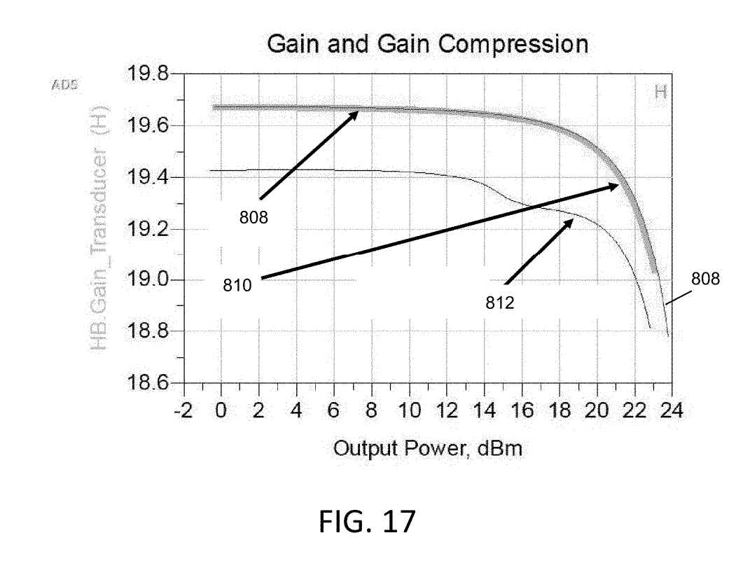

FIGS. 16-17 are graphs of power amplifier gain versus output power of the present invention. The inventive LNAs 600, 700 with high impedance in FIGS. 14-15 experience a relatively small drop in power, as shown in the curve 800 in FIG. 16, compared to when no LNA is present in the circuit 100 of FIG. 9, as shown in the curve 802. However, as shown in the curve 804 in FIG. 16, the LNA of the prior art adds a relatively large amount of distortion. Similarly, as shown in FIG. 17, the inventive LNAs with high impedance in FIGS. 14-15 have gain and gain compression depending on the presence of the pull-up resistors Roff1 and Roff2. As shown in FIG. 17, the curve 808 corresponds to the gain of the inventive LNA circuits in FIGS. 14-15, which is nearly identical to the curve 810 of the inventive LNA circuit without the pull-up resistor Roff1. In contrast, the curve 812 corresponds to the gain of the inventive LNA circuits in FIGS. 14-15 without both of the pull-up resistors Roff1 and Roff2, with curve 812 demonstrating significantly reduced gain.

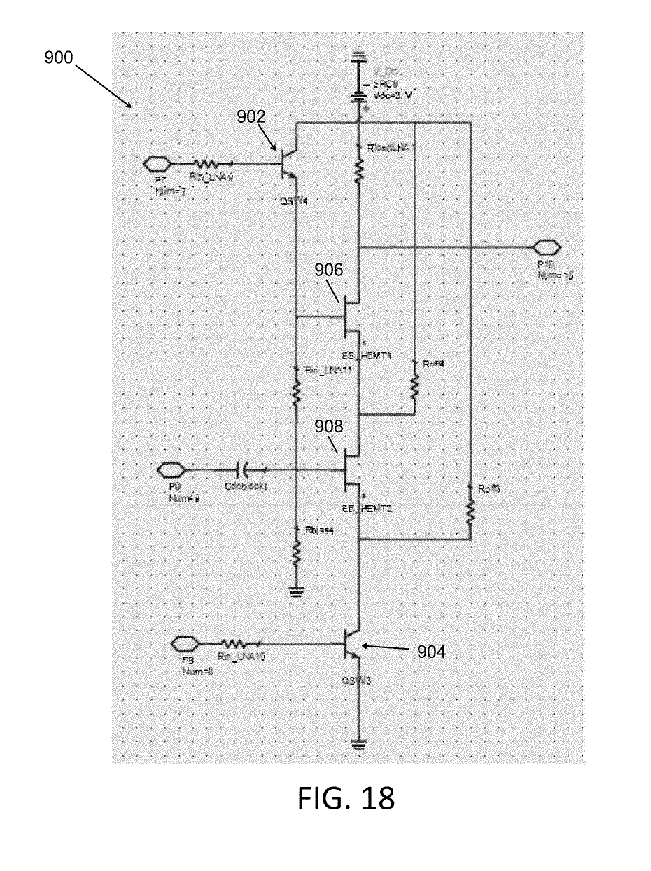

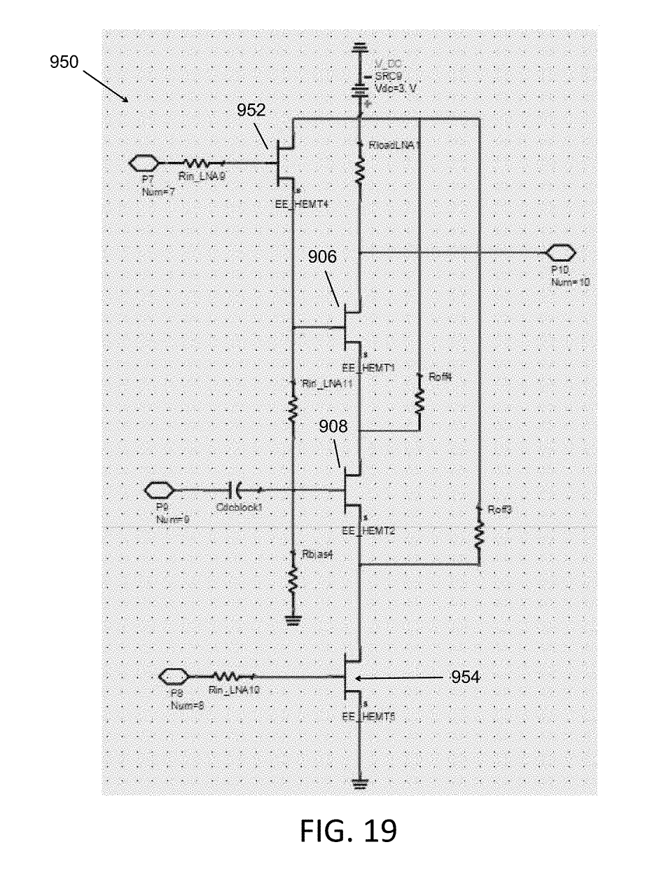

FIGS. 18-19 are alternative embodiments of the high impedance LNA circuit of the present invention using FETs, which provide the circuits with better noise performance. Referring to FIG. 18, the high impedance LNA circuit 900 includes bipolar transistors 902, 904 as well as FETs 906, 908. Referring to FIG. 19, the high impedance LNA circuit 950 includes FETs 952, 954 as well as FETs 906, 908.

The high impedance LNAs of the present invention, as shown in various embodiments in FIGS. 14-15 and 18-19, allow a high impedance to be seen by the PA 112 at the antenna terminal in the circuit 100 in FIG. 9. This is true for both small and large signal operations. The LNA circuit 600 represented in FIG. 14 represents one embodiment of a high impedance LNA of the present invention, with the DC switch transistor QSW1 602 having its base grounded, causing a DC open circuit to resistors Rbias1, Rin_LNA3, and Rbias3. This causes the bases of transistors Qcascode and Qamp to be about zero VDC. Referring to FIG. 14, the base of transistor QSW2 604 is grounded, causing the emitter of Qamp to be a DC OPEN circuit.

One significant aspect of the high impedance LNAs of the present invention are pull-up resistors Roff1 and Roff2, shown in FIG. 14, which correspond to Roff4 and Roff3, respectively, in the alternative embodiments shown in FIGS. 15 and 18-19. Referring to the embodiment in FIG. 14, these resistors Roff1 and Roff2 cause the emitters of Qamp and Qcascode of the LNA 600 of FIG. 14 to pull up to the power supply voltage, which is about 3V in this case. Accordingly, the switch QSW2 604 sees a 3V collector voltage which is a high DC, and also sees RF impedance since the collector base is reverse biased by 3V.

Therefore, at RFin, which is the input to the LNA 600 in FIG. 14, there appears to be a very high impedance and virtually an open circuit to the PA 112 in FIG. 9. When the LNA 600 is in this high impedance (Z) state, all the transistors are OFF. When the peak-to-peak voltage at the input RFin, received from the PA, is very large, for example, about 8V pk-pk, which may be 24 dbm into 50 ohms, the input of the LNA 600 remains a high impedance. From the RFin pin to Qamp under a large signal, the base-emitter and base-collector diodes become forward biased. However, from the standpoint of the Qamp collector or emitter, there are two other reverse biased diodes from QSW2 604 and Qcascode.

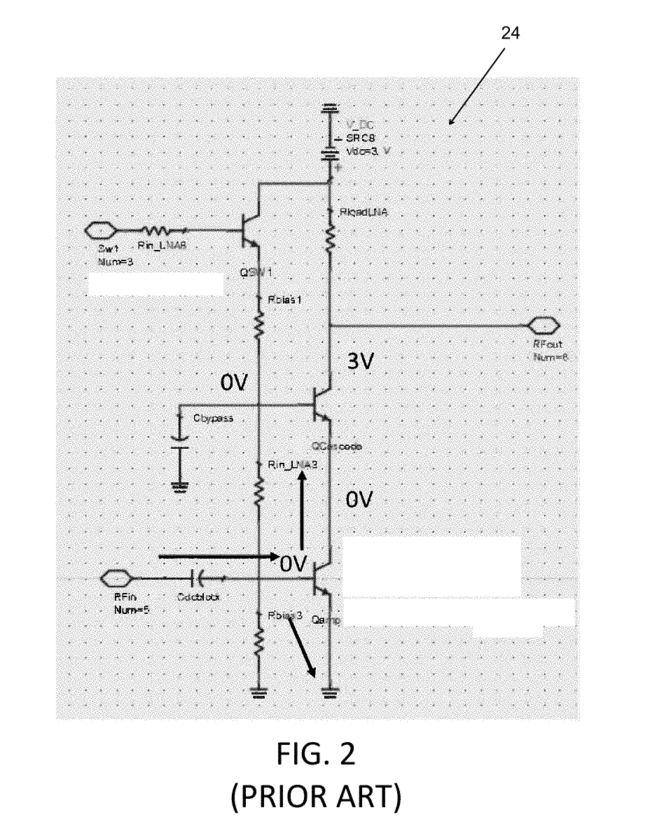

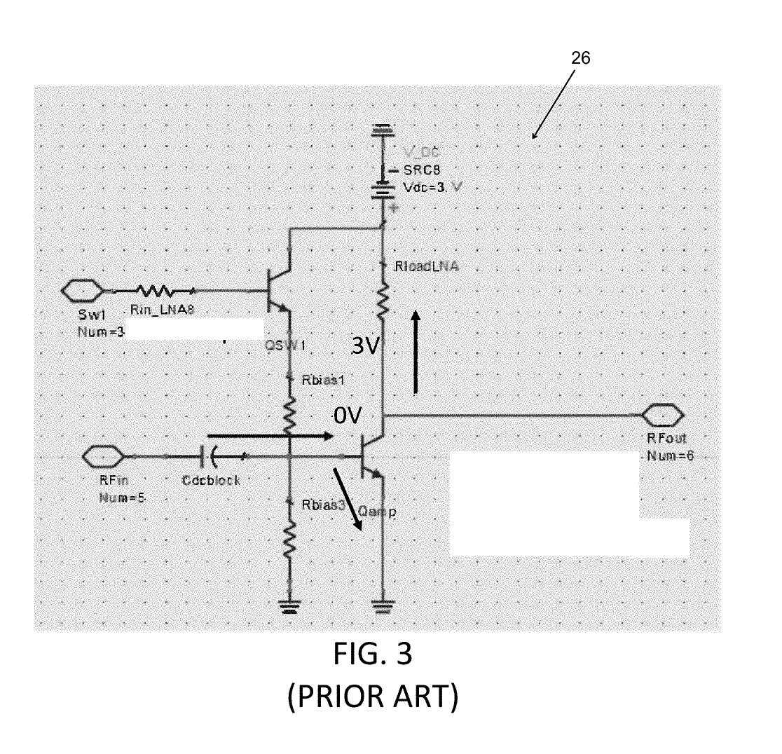

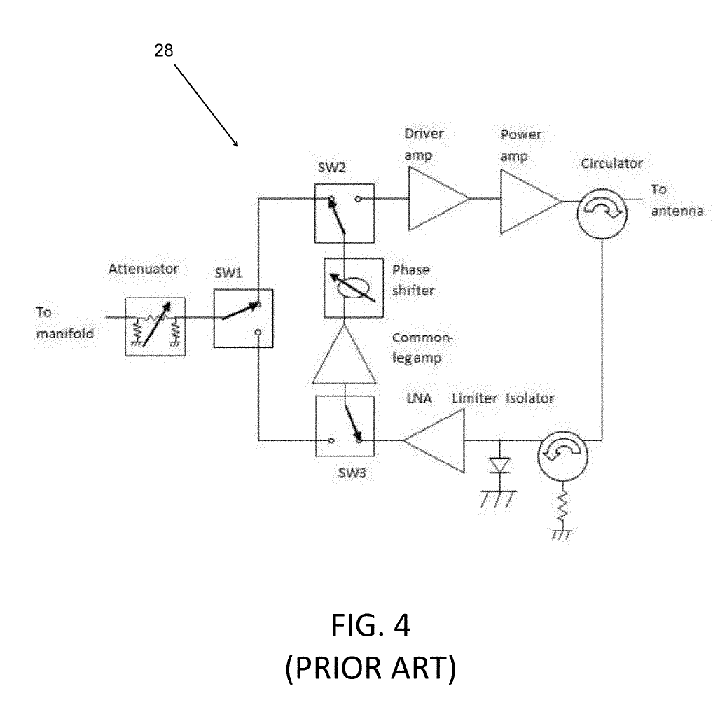

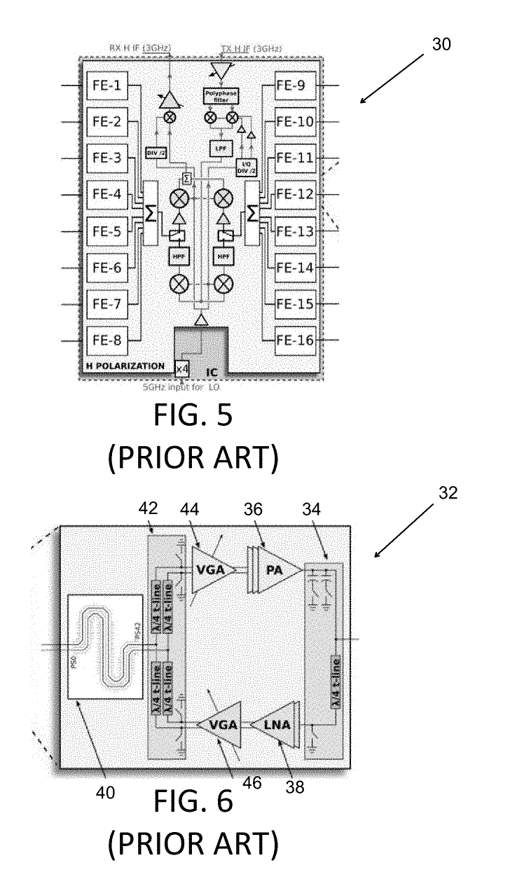

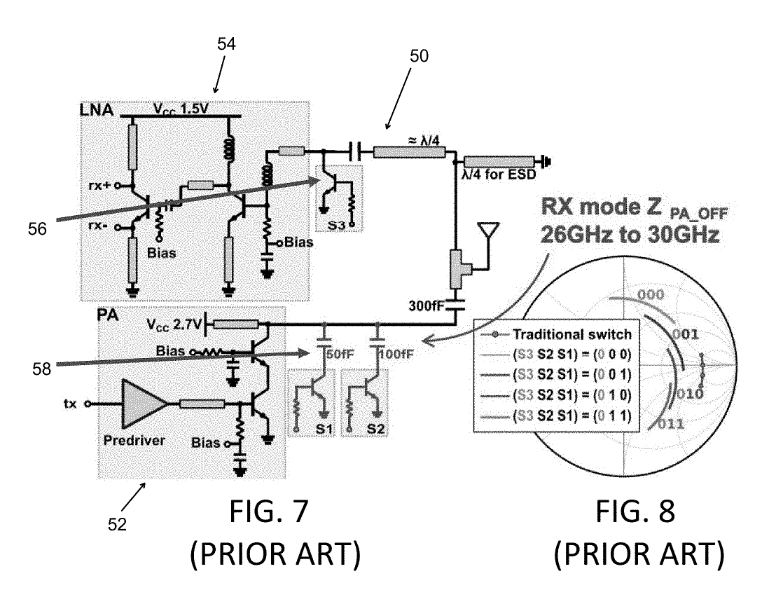

On the contrary, both of the prior art LNA circuits 24, 26 in FIGS. 2-3, respectively, have a large zero bias capacitance from the base-emitter and base-collector terminals. The prior art LNAs 24, 26 will also have forward biased junctions to ground or to the positive power supply under large signals.

Referring again to FIGS. 16-17, simulations are shown of performance of the architecture of the T-R circuit in FIG. 2 in the transmit mode. With no LNA connected, the PA shows a compressed power gain of about 19.8 dB and a compressed power of about 24 dBm. When a high impedance LNA is implemented, such as the high impedance LNA 600 of the present invention shown in FIG. 14, there is only about 0.1 dB drop in gain and power. However, using the prior art LNAs, the gain of the PA starts dropping at about 12 dBm of power. This corresponds to about 2.5V pk-pk at the LNA input RFin. Thus, the use of prior art LNAs will cause unwanted distortion at the antenna output, and at higher power values, the prior art LNAs could be damaged because of the large base input currents.

FIG. 17 shows the effect of the pull-up resistors Roff1 and Roff2 of the high impedance LNA of the present invention, shown in FIG. 14 and in alternative embodiments in FIGS. 15 and 18-19. Without both pull-up resistors in the high impedance LNAs of the present invention, the distortion of RF signals, shown in the curve 812, is as bad as in the LNAs of the prior art. Accordingly, pull-up resistors should be implemented in the high impedance LNAs 600, 700, 900, 950 of the present invention, shown in FIGS. 14-15 and 18-19, respectively.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A circuit comprising:
a power amplifier (PA) having a PA output operatively connected to an antenna; and
a low noise amplifier (LNA) having:
an LNA input connected to the antenna; and
an LNA output;
wherein when the circuit is in a transmit mode, the power amplifier is in an ON state, and the low noise amplifier is in an OFF state, whereby the low noise amplifier has a high impedance between the LNA input and the LNA output to block a first signal from the LNA input from reaching the antenna.

2. The circuit of claim 1, wherein the high impedance is about 50 ohms.

3. The circuit of claim 1, wherein when the circuit is in a receive mode, the power amplifier is in an OFF state, and the low noise amplifier is in an ON state, whereby the low noise amplifier has a low impedance between the LNA input and the LNA output to allow a second signal from the antenna to be amplified by the low noise amplifier for output at the LNA output.

4. The circuit of claim 3, wherein the low impedance is about 3 ohms.

5. The circuit of claim 1, wherein the low noise amplifier further comprises a plurality of transistors which are only bipolar transistors.

6. The circuit of claim 1, wherein the low noise amplifier further comprises a plurality of transistors including at least one bipolar transistor and at least one field-effect transistor.

7. The circuit of claim 1, further comprising:
an inductor in series between the power amplifier and the antenna; and
a first capacitor in parallel with the inductor.

8. The circuit of claim 7, further comprising:
a second capacitor in parallel with the power amplifier.

9. The circuit of claim 1, further comprising:
a resistor and a capacitor in parallel with the low noise amplifier; and
wherein the parallel combination of the resistor, the capacitor, and the low noise amplifier is in series with the antenna.

10. A time-division duplex (TDD) circuit comprising:
a power amplifier (PA) having a PA output operatively connected to an antenna; and
a low noise amplifier (LNA) having:
an LNA input connected to the antenna; and
an LNA output;
wherein when the circuit is in a transmit mode, the power amplifier is in an ON state, and the low noise amplifier is in an OFF state, whereby the low noise amplifier has a high impedance between the LNA input and the LNA output to block a first signal from the LNA input from reaching the antenna; and
wherein when the circuit is in a receive mode, the power amplifier is in an OFF state, and the low noise amplifier is in an ON state, whereby the low noise amplifier has a low impedance between the LNA input and the LNA output to allow a second signal from the antenna to be amplified by the low noise amplifier for output at the LNA output.

11. The TDD circuit of claim 10, wherein the high impedance is about 50 ohms.

12. The TDD circuit of claim 10, wherein the low impedance is about 3 ohms.

13. The TDD circuit of claim 10, wherein the low noise amplifier further comprises a plurality of transistors which are only bipolar transistors.

14. The TDD circuit of claim 10, wherein the low noise amplifier further comprises a plurality of transistors including at least one bipolar transistor and at least one field-effect transistor.

15. The TDD circuit of claim 10, further comprising:
an inductor in series between the power amplifier and the antenna; and
a first capacitor in parallel with the inductor.

16. The TDD circuit of claim 15, further comprising:
a second capacitor in parallel with the power amplifier.

17. The TDD circuit of claim 10, further comprising:
a resistor and a capacitor in parallel with the low noise amplifier; and
wherein the parallel combination of the resistor, the capacitor, and the low noise amplifier is in series with the antenna.

18. A low noise amplifier (LNA) comprising:
an LNA input;
an LNA output; and
a plurality of transistors in series;
wherein when the low noise amplifier is in an OFF state, the low noise amplifier has a high impedance between the LNA input and the LNA output to block a first signal from the LNA input; and
wherein when the low noise amplifier is in an ON state, the low noise amplifier has a low impedance between the LNA input and the LNA output to allow a second signal at the LNA input to be amplified by the low noise amplifier for output at the LNA output.

19. The low noise amplifier of claim 18, wherein the plurality of transistors is in a cascode configuration, are reverse biased, and has a low capacitance.

20. The low noise amplifier of claim 18, wherein at least two of the plurality of transistors are field-effect transistors (FETs).
